(19) United States
(12) Patent Application Publication
(10) Pub. No.: US 2007/0039924 A1
(43) Pub. Date: Feb. 22, 2007

(54) Low-temperature oxide removal using fluorine

(75) Inventors: Anthony Dip, Cedar Creek, TX (US); Allen John Leith, Austin, TX (US); Seungho Oh, Austin, TX (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/206,056

(22) Filed: Aug. 18, 2005

(51) Int. Cl. C03C 25/68; B44C 1/22; H01L 21/302; H01L 21/461

(52) U.S. Cl. 216/79; 216/58; 438/715

(57) ABSTRACT

A method and system for processing a substrate includes providing the substrate in a process chamber, the substrate having an oxide layer formed thereon, and exposing the substrate to an etching gas containing F₂ gas at a first temperature to remove the oxide layer from the substrate. The substrate may subsequently be heated to a second temperature greater than the first temperature, and a film may then be formed on the substrate at the second temperature. In one embodiment, a Si film is epitaxially formed on a Si substrate.

### CROSS REFERENCE TO RELATED APPLICATIONS

The present invention is related to U.S. patent application Ser. No. 10/673,375, titled “DEPOSITION OF SILICON-CONTAINING FILMS FROM HEXACHLORODISILANE,” U.S. patent application Ser. No. 11/094,462, titled “A METHOD AND SYSTEM FOR REMOVING AN OXIDE FROM A SURFACE,” and U.S. patent application Ser. No. 10/647,534, titled “MULTIPLE GROW-ETCH CYCLIC SURFACE TREATMENT FOR SUBSTRATE PREPARATION,” the entire contents of all of which are hereby incorporated by reference.

### FIELD OF THE INVENTION

The present invention relates to semiconductor processing, and more particularly, to a low-temperature process for oxide removal from a substrate and subsequent formation of a film on the substrate.

### BACKGROUND OF THE INVENTION

Silicon-containing films are used for a wide variety of applications in the semiconductor industry. Silicon-containing films include silicon films such as epitaxial silicon, polycrystalline silicon (poly-Si), amorphous silicon, epitaxial silicon germanium (SiGe), silicon germanium carbide (SiGeC), silicon carbide (SiC), silicon nitride (SiN), silicon carbonitride (SiCN), and silicon carboxide (SiCO). As circuit geometries shrink to ever smaller feature sizes, lower processing temperatures are preferred, for example because of introduction of new materials into semiconductor devices and reduction of thermal budgets of shallow implants in source and drain regions. Moreover, it is evident that non-selective (blanket) and selective deposition of silicon-containing films will be needed for future devices.

Epitaxial silicon deposition is a process where the crystal lattice of the bulk silicon is extended through growth of a new silicon-containing film that may have a different doping level than the bulk. Matching target epitaxial film thickness and resistivity parameters is important for the subsequent fabrication of properly functioning devices. Prior to depositing a silicon-containing film, e.g., epitaxial silicon or epitaxial silicon germanium films, on a silicon substrate, it may be required to remove a native oxide layer from the surface of the substrate in order to prepare a proper starting growth surface (i.e., a seed layer) to deposit a high quality epitaxial film. A native oxide layer, which may be a few to several Angstroms (Å) thick, for example, forms easily on clean silicon surfaces when exposed to an oxygen-containing environment (e.g., air), even at room temperature and atmospheric pressure. If the substrate is not cleaned prior to depositing a silicon-containing film on the substrate, i.e., all oxygen and other contaminants have not been properly removed from the substrate surface, then the silicon-containing film subsequently deposited on the substrate will not grow epitaxially and may contain defects that can lead to a high leakage current through the film and cause the microelectronic device to not perform optimally.

Similarly, a poly-Si film can be deposited directly on a poly-Si film to form an electrical contact. However, because other processing typically occurs between the poly-Si deposition steps, the substrates (wafers) can be removed from the processing system between the deposition steps, in which case a native oxide layer can form on the substrates. If the native oxide layer is not removed prior to depositing the poly-Si film, the resulting contact can have high electrical resistance.

It may also be necessary to remove a native oxide layer from a substrate, for example, prior to depositing a high dielectric constant (high-k) layer on the substrate, where the high-k film is a part of a gate stack. Examples of high-k films include HfO₂, HfSiOₓ, HfSiOₓN_{y}, ZrO₂, ZrSiOₓ, and ZrSiOₓN_{y}. The presence of an oxide layer can reduce the effective dielectric constant of the gate stack since the oxide layer normally has a lower dielectric constant than the high-k film. Thus, a higher dielectric constant and higher level of control over the overall dielectric constant can be achieved if the oxide layer is effectively removed before depositing a high-k film.

Traditionally, a high-temperature annealing of above 900° C. in a hydrogen atmosphere has been used in (vertical) batch processing systems to remove a native oxide layer from substrates and clean the substrates of other impurities prior to a deposition process. However, such a high-temperature process does not meet current or future thermal budget needs for many advanced processes. For example, current gate lengths and modern microelectronic structures limit devices to a reduced thermal budget.

Plasma processing has been found to allow lowering of the substrate temperature during processing and thus offers an alternative to high-temperature annealing in a hydrogen atmosphere. However, exposure of the substrate to a plasma source can damage the substrate as a result of the interaction of excited species in the plasma with the substrate. Another oxide removal method is based on hydrogen fluoride (HF), but the use of HF can result in incomplete oxide removal and unwanted erosion of the substrate and various films on the substrate.

### SUMMARY OF THE INVENTION

Embodiments of the invention address the above-described problems associated with removing an oxide layer from a substrate. Embodiments of the invention can allow removal of an oxide layer from a substrate at a low process temperature while reducing damage to the substrate, thereby providing flexibility in the temperature of an oxide removal step. Embodiments of the invention can also allow removal of an oxide layer from a substrate using an etchant gas that is not as aggressive as, and much safer to handle than, conventional etchant gases including, for example, NF₃ or CLF₃.

According to an embodiment of the invention, a method is provided for removing an oxide layer from a substrate at low substrate temperature and subsequently forming a low defect film on the substrate.

According to an embodiment of the invention, the method includes (1) providing a substrate in a process chamber of a processing system, the substrate having an oxide layer formed thereon, and (2) exposing the substrate to an etching gas containing F₂ at a first substrate temperature to remove the oxide layer from the substrate. According to an embodiment of the invention, the method may further include (3) heating the substrate to a second temperature greater than the first substrate temperature, and, optionally, (4) forming a film on the substrate at the second substrate temperature.

According to an embodiment of the invention, the substrate can contain Si, SiGe, Ge, a glass substrate, a LCD substrate, or a compound semiconductor. According to another embodiment of the invention, the film can be a Si-containing film, such as Si or SiGe, or a high-k dielectric film, such HfO₂, HfSiOₓ, HfSiOₓN_{y}, ZrO₂, ZrSiOₓ, or ZrSiOₓN_{y}.

According to an embodiment of the invention, the method includes (1) providing a Si substrate in a process chamber of a processing system, the Si substrate having an oxide layer formed thereon and (2) exposing the Si substrate to an etching gas containing F₂ at a first substrate temperature lower than about 500° C. to remove the oxide layer from the Si substrate. According to an embodiment of the invention, the method may further include (3) heating the Si substrate to a second temperature between about 100° C. and about 900° C., and, optionally, (4) forming a Si film on the substrate at the second substrate temperature. According to an embodiment of the invention the Si substrate and the Si film can be epitaxial Si. According to another embodiment of the invention, the Si substrate and the Si film can be poly-Si.

### BRIEF DESCRIPTION OF THE DRAWINGS

The features, advantages thereof, and technical and industrial significance of embodiments of the present invention will be better understood by reading the following detailed description of the preferred embodiments when considered in connection with the accompanying drawings, in which:

FIG. 1 illustrates a simplified block diagram of a batch processing system according to an embodiment of the invention;

FIG. 2A illustrates a flow diagram for oxide removal from a substrate in a batch processing system and subsequent deposition of a film onto the substrate according to an embodiment of the invention;

FIG. 2B illustrates the variation in substrate temperature as a function of processing time for oxide removal from a substrate and subsequent deposition of a film onto the substrate according to an embodiment of the invention;

FIGS. 3A-3C schematically illustrate oxide removal from a substrate and subsequent deposition of a film onto the substrate according to an embodiment of the invention;

FIGS. 4A-4B illustrates Secondary Ion Mass Spectroscopy (SIMS) depth profiles of Si films deposited onto Si substrates with and without oxide removal according to an embodiment of the invention; and

FIGS. 5A-5D schematically illustrate oxide removal from a patterned structure and subsequent deposition of a film onto the patterned structure according to an embodiment of the invention.

### DETAILED DESCRIPTION OF PREFERRED EMBODIMENTS

Embodiments of the invention may be used for native oxide removal (NOR) from a substrate prior to depositing a film onto the substrate. For example, the native oxide removal can be carried out prior to forming an epitaxial Si film, a poly-Si film, or a high-k film on a Si substrate. Embodiments of the invention may also be used to remove other types of oxides than native oxides, such as thin chemical oxides film grown or deposited on substrates, for example.

In the following description, the terms native oxide layer and oxide layer are used interchangeably to refer to any oxide layer to be removed from a substrate prior to forming a film on the substrate. For a Si substrate, an oxide layer or a native oxide layer can, for example, be a SiO₂ layer or a SiOₓ (x<2) layer. Further, in order to facilitate a thorough understanding of the invention and for purposes of explanation, specific details are set forth, such as a particular geometry of the batch processing system and descriptions of various components. However, it should be understood that the invention may be practiced in other embodiments that depart from these specific details which are not limiting in any way.

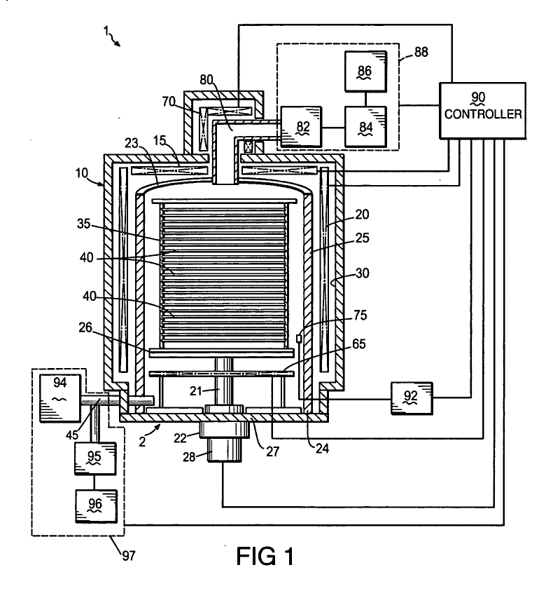

FIG. 1 illustrates a simplified block diagram of a batch processing system according to an embodiment of the invention. The batch processing system 1 contains a process chamber 10 and a process tube 25 that has an upper end 23 connected to an exhaust pipe 80, and a lower end 24 hermetically joined to a lid 27 of cylindrical manifold 2. The exhaust pipe 80 discharges gases from the process tube 25 to a vacuum pumping system 88 to maintain a pre-determined atmospheric or below atmospheric pressure in the processing system 1. A substrate holder 35 for holding a plurality of substrates (wafers) 40 in a tier-like manner (in respective horizontal planes at vertical intervals) is placed in the process tube 25. The substrate holder 35 resides on a turntable 26 that is mounted on a rotating shaft 21 penetrating the lid 27 and driven by a motor 28. The turntable 26 can be rotated during processing to improve overall film uniformity or, alternately, the turntable can be stationary during processing. The lid 27 is mounted on an elevator 22 for transferring the substrate holder 35 in and out of the process tube 25. When the lid 27 is positioned at its uppermost position, the lid 27 is configured to close the open end of the manifold 2.

A gas delivery system 97 is configured to introduce gases into the process chamber 10. A plurality of gas supply lines can be arranged around the manifold 2 to supply a plurality of gases into the process tube 25 through the gas supply lines. For simplicity, only one gas supply line 45 among the plurality of gas supply lines is shown in FIG. 1. The gas supply line 45 is connected to a first gas source 94. In general, the first gas source 94 can supply gases for processing the substrates 40, including gases for forming films (e.g., silicon-containing gases for depositing silicon-containing films) onto the substrates 40, or an etching gas containing F₂ for removing oxide layers from the substrates 40.

Alternatively, or in addition, one or more of the gases can be supplied from the (remote) plasma source 95 that is operatively coupled to a second gas source 96 and to the process chamber 10 by the gas supply line 45. The plasma-excited gas is introduced into the process tube 25 by the gas supply line 45. The plasma source 95 can, for example, be a microwave plasma source, a radio frequency (RF) plasma source, or a plasma source powered by light radiation. In the case of a microwave plasma source, the microwave power can be between about 500 Watts (W) and about 5,000 W. Examples of microwave frequencies that could be used are 2.45 GHz or 8.3 GHz. In one example, the remote plasma source can be a Downstream Plasma Source Type AX7610, manufactured by MKS Instruments, Wilmington, Mass., USA.

A cylindrical heat reflector 30 is disposed so as to cover the reaction tube 25. The heat reflector 30 has a mirror-finished inner surface to suppress dissipation of radiation heat radiated by a main heater 20, a bottom heater 65, a top heater 15, and an exhaust pipe heater 70. A helical cooling water passage (not shown) is formed in the wall of the process chamber 10 as a cooling medium passage. The heaters 20, 65, and 15 can, for example, maintain the temperature of the substrates 40 between about 20° C. and about 900° C.

The vacuum pumping system 88 comprises a vacuum pump 86, a trap 84, and an automatic pressure controller (APC) 82. The vacuum pump 86 can, for example, include a dry vacuum pump capable of a pumping speed up to 20,000 liters per second (and greater). During processing, gases can be introduced into the process chamber 10 via the gas supply line 45 of the gas delivery system 97 and the process pressure can be adjusted by the APC 82. The trap 84 can collect unreacted precursor material and by-products from the process chamber 10.

The process monitoring system 92 comprises a sensor 75 capable of real-time process monitoring and can, for example, include a mass spectrometer (MS), a Fourier Transform Infrared (FTIR) spectrometer, or a particle counter. A controller 90 includes a microprocessor, a memory, and a digital I/O port capable of generating control voltages sufficient to communicate and activate inputs to the processing system 1 as well as monitor outputs from the processing system 1. Moreover, the controller 90 is coupled to, and can exchange information with, gas delivery system 97, motor 28, process monitoring system 92, heaters 20, 15, 65, and 70, and vacuum pumping system 88. The controller 90 may be implemented as a DELL PRECISION WORKSTATION 610™. The controller 90 may also be implemented as a general purpose computer, processor, digital signal processor, etc., which causes a substrate processing apparatus to perform a portion or all of the processing steps of the invention in response to the controller 90 executing one or more sequences of one or more instructions stored in a computer readable medium. The computer readable medium or memory is configured to hold instructions programmed according to the teachings of the invention and to store data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

The controller 90 may be locally located relative to the processing system 1, or it may be remotely located relative to the processing system 1 via the internet or an intranet. Thus, the controller 90 can exchange data with the processing system 1 using at least one of a direct connection, an intranet, and the internet. The controller 90 may be coupled to an intranet at a customer site (i.e., a device maker, etc.), or coupled to an intranet at a vendor site (i.e., an equipment manufacturer). Furthermore, another computer (i.e., controller, server, etc.) can access controller 90 to exchange data via at least one of a direct connection, an intranet, and the internet.

It is to be understood that the batch processing system 1 depicted in FIG. 1 is shown for exemplary purposes only, as many variations of the specific hardware can be used to practice the present invention, and these variations will be readily apparent to one having ordinary skill in the art. The processing system 1 in FIG. 1 can, for example, process substrates of any size, such as 200 mm substrates, 300 mm substrates, or even larger substrates. Furthermore, the processing system 1 can simultaneously process up to about 200 substrates, or more. Alternatively, the processing system can simultaneously process up to about 25 substrates. In addition to semiconductor substrates, e.g., Si, SiGe, or Ge, the substrates can, for example, contain LCD substrates, glass substrates, or compound semiconductor substrates.

The inventors of the present invention have realized that traditional high-temperature hydrogen anneals of above 900° C. that are performed to remove an oxide layer and other impurities from a substrate prior to processing do not meet current or future thermal budget needs. Further, plasma assisted processes, while performed at lower temperatures, can result in damage to a substrate. Thus, lower-temperature non-plasma processes for removing an oxide layer are needed that are compatible with advanced device processing requiring a low thermal budget. Based on this recognition, the present inventors studied the use of fluorine containing gas in a low-temper non-plasma etch process. Fluorine containing gasses are known to have aggressive etch characteristics that were thought to be suitable only for aggressive etch processes. For example, NF₃ and CLF₃ have been used in chamber cleaning processes wherein deposited materials are removed from interior surfaces of the chamber. Further, U.S. Pat. No. 6,194,327 discloses use of a fluorine gas for rapid thermal etching of thick sacrificial oxide layers. However, this process is performed at temperatures of 800-1200° C., which as with annealing discussed above, is too high for current and future thermal budget requirements. Moreover, the present inventors have recognized that this process is too aggressive, and can result in etching of the underlying substrate or in a rough substrate surface unsuitable for subsequent film deposition.

In studying the use if fluorine gas for etching oxides, the present inventors have discovered that F₂ gas applied at substrate temperature of less than about 400° C. can provide acceptable etching characteristics for thin native oxides that can be 10 angstroms or less in thickness, and are typically as thin as 2-3 angstroms. The upper limit originates from the fact that the underlying Si substrate becomes rough if the substrate temperature is too high. The inventors have seen this effect, even at about 300° C. However, roughening effects at this temperature may be acceptable for some applications. This effect is (in part) due to faster etching rate of the underlying Si substrate compared to the overlying native oxide layer. This faster etching of Si vs oxide has been observed when etching oxide layers formed on a Si substrate in a deposition process from TEOS gas. At 200° C. the (poly) Si etch rates were about 2.5 angstrom/min and the oxide etch rates were about 0.07 angstrom/min. At 300° C. the (poly) Si etch rates were about 8 angstrom/min and the oxide etch rates were about 0.1 angstrom/min.

Embodiments of the invention further provide formation of a film on the substrate following removal of the oxide layer. The oxide layer is removed at first substrate temperature and the substrate can be heated to a second substrate temperature, greater than the first substrate temperature, at which a film can be formed on the substrate by exposing the substrate to a deposition gas. Thus, the oxide removal step according to embodiments of the invention is not restricted based on processing temperatures of other process steps.

In one embodiment, the film is formed on the substrate at a second substrate temperature greater than the first substrate temperature to achieve deposition rates that are high enough for device manufacturing and to ensure that the deposited film has the desired material properties. The desired material properties can, for example, include a crystal structure (i.e., epitaxial, polycrystalline, or amorphous), and elemental composition. Furthermore, the second substrate temperature can be selected to provide selective film deposition on exposed silicon-containing surfaces of the substrate, or non-selective (blanket) film deposition on the whole substrate. In order to prevent formation of a new oxide layer on the substrate, the silicon-containing film can be formed on the substrate following the oxide removal step without exposing the substrate to ambient air or other oxygen-containing ambients.

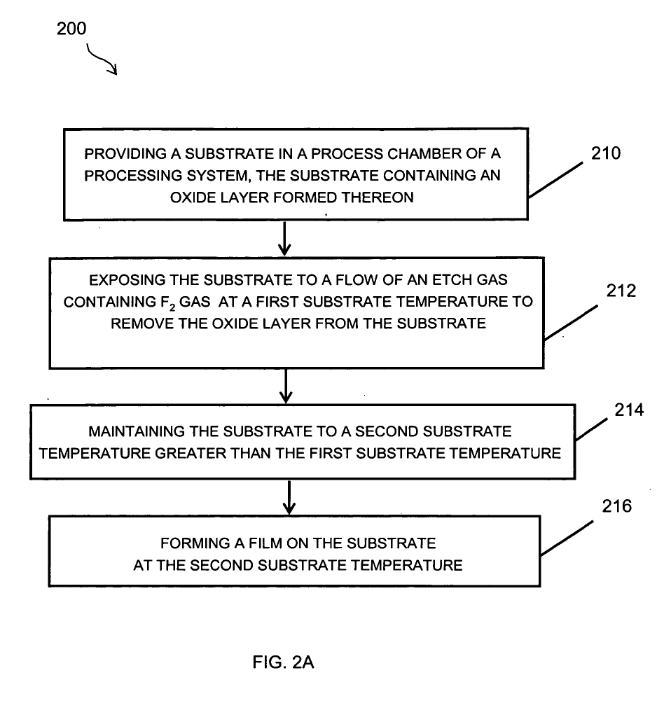

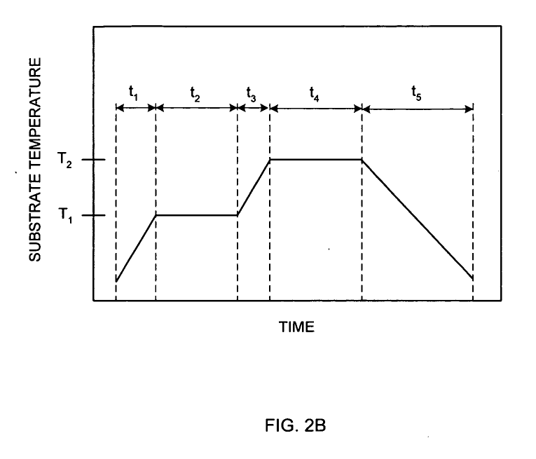

FIG. 2A illustrates a flow diagram for oxide removal from a substrate in a process chamber and subsequent deposition of a film onto the substrate according to an embodiment of the invention. FIG. 2B illustrates the variation in substrate temperature as a function of processing time for oxide removal from a substrate and subsequent deposition of a film onto the substrate according to an embodiment of the invention. Referring now to FIG. 2A, the process 200 includes, at 210, providing a substrate in a process chamber of a processing system, the substrate having an oxide layer formed thereon. The processing system can, for example, be the batch processing system 1 depicted in FIG. 1. Alternatively, the processing system can be a single wafer processing system. The substrate can, for example, be a semiconductor substrate, such as a silicon substrate, a silicon germanium substrate, a germanium substrate, a glass substrate, a LCD substrate, or a compound semiconductor substrate, and can include numerous active devices and/or isolation regions. Furthermore, the substrate can contain vias or trenches or combinations thereof.

After providing a substrate in the process chamber in 210, the substrate is heated to a first substrate temperature T₁ during time period t₁ as shown in FIG. 2B. In one embodiment, T₁ is less than about 400° C. to reduce process damage, such as etch damage to the substrate or to other materials on the substrate. The time period t₁ is a transition step and can, for example, be between about 2 min and about 15 min, but this is not required in embodiments of the invention.

At 212, during time period t₂, the substrate is exposed to a flow of an etching gas containing F₂ gas at the first substrate temperature T₁ lower than about 400° C. to remove the oxide layer from the substrate. The first substrate temperature T₁ can be selected in consideration of the overall thermal budget and/or to allow efficient removal of the oxide layer from the substrate while minimizing damage such as etching of the substrate material or other materials formed on the substrate material. For example, where a thermal budget allows for higher temperatures and substrate etching is of little concern, then T₁ may approach about 400° C. However, with lower thermal budgets or damage is a concern, the substrate temperature can be much lower, although the etch rate may also be lowered. Exemplary run times for the F₂ native oxide removal stop are about 15 minutes at 300° C., or 90 minutes at 200° C. According to an embodiment of the invention, the first substrate temperature can be less than about 400° C. and greater than about 20° C., or between about 100° C. and about 300° C. or between 200° C. and 300° C. According to an embodiment of the invention, the first substrate temperature can be about 200° C.

According to an embodiment of the invention, the processing conditions for the oxide removal can include a gas pressure between about 0.1 Torr and about 100 Torr in the process chamber. Alternatively, the gas pressure can be between about 1 Torr and about 10 Torr in the process chamber. The etching gas for the oxide removal step contains F₂ gas and can further contain an inert gas. The inert gas can, for example, contain N₂, argon (Ar), helium (He), neon (Ne), krypton (Kr), or xenon (Xe), or a combination of two or more thereof. According to one embodiment of the invention, the etching gas contains F₂ gas, an inert gas, and a reducing gas. The reducing gas can, for example, contain H₂, H, or NH₃, or other hydrogen-containing gases. The reducing gas can aid in the decomposition of F₂ on the substrate at low substrate temperature. According to an embodiment of the invention, the reducing gas can be plasma-excited in a remote plasma source. A gas flow rate between about 0.010 standard liters per minute (slm) and about 20 slm can be used for the etching gas. As those skilled in the art will readily appreciate, the inert gas can be used to control the concentration of F₂ in the etching gas.

Generally, the F₂ etchant gas is diluted to 20% F₂ and 80% N₂ from a gas source. However, the mixture may be diluted to provide from 3-20% F₂, with the remaining gas N₂. Exemplary compositions and flows of the etching gas include 8.8 slm N₂ and 0.2 slm F₂ (8 slm N₂+1 slm of 20% F₂ in N₂), and 8.6 slm N₂ and 0.4 slm F₂ (7 slm N₂+2 slm of 20% F₂ in N₂), but embodiments of the invention are not limited to those compositions and gas flows.

While not required to practice the present invention in one embodiment, following removal of the oxide layer from the substrate, at 214, the substrate is heated during time period t₃ from the first substrate temperature T₁ to a second substrate temperature T₂ greater than the first substrate temperature T₁. The process chamber may be evacuated prior to or during the time period t₃ to minimize etch damage to the substrate. Time period t₃ is a transition step and may be variable in length depending on system design and processing temperature differences between the oxide removal step at substrate temperature T₁ and the substrate temperature T₂. The time period t₃ can, for example, be between about 5 min and about 45 min, but this is not required in embodiments of the invention. According to an embodiment of the invention, the second substrate temperature T₂ can be between about 100° C. and about 900° C. According to another embodiment of the invention, the second substrate temperature T₂ can be between about 650° C. and about 750° C. According to yet another embodiment of the invention, the second substrate temperature T₂ can be between about 750° C. and about 850° C.

At 216, a film is formed on the substrate at the second substrate temperature T₂. The film is formed on the substrate following the removal of the oxide layer without exposing the substrate to ambient air that can form an oxide layer on the substrate. According to an embodiment of the invention, the film can be a silicon-containing film that is formed on the substrate by exposing the substrate to a gas containing a silicon-containing gas, for example, SiH₄, SiCl₄, Si₂H₆, SiH₂Cl₂, or Si₂Cl₆, or a combination of two or more thereof. According to an embodiment of the invention, the silicon-containing gas can further contain a germanium-containing gas, including, for example, GeH₄, GeCl₄, or a combination thereof, for depositing a SiGe film on the substrate. As described above, the silicon-containing film can be formed by providing a silicon-containing gas from a non-plasma gas source such as the gas source 94 in FIG. 1. Alternatively, a silicon-containing gas from the second gas source 96 may be excited by the plasma source 95 to assist in the deposition of a silicon-containing film on the substrate. Time period t₄ is a film forming step and generally depends on the desired film thickness. For many applications with film thickness less than about 500 angstroms, the time period t₄ can be less than about one hour. According to another embodiment of the invention, the film can be a high-k film, for example HfO₂, HfSiOₓ, HfSiOₓN_{y}, ZrO₂, ZrSiOₓ, or ZrSiOₓN_{y}.

When a film with a desired thickness has been formed on the substrate, flow of the deposition gas is stopped, the substrate is allowed to cool down during time period t₅, and the substrate is subsequently removed from the process chamber. Like time periods t₁ and t₃, the time period t₅ is a transition step and may be variable in length. Time period t₅ can, for example, be between about 2 min and about 15 min, but this is not required in embodiments of the invention.

Although not shown in FIG. 2A, purging steps may be performed in between the steps of the process 200. For example, the process chamber may be purged during time period t₃ between the oxide removal step 212 and the film forming step 216 to keep the substrate surface clean. The purge gas can, for example, contain H₂, an inert gas such as N₂, or a noble gas. Furthermore, one or more of the purge steps may be replaced or complemented with pump down steps where no purge gas is flowed.

As would be appreciated by those skilled in the art, each of the steps or stages in the flowchart of FIG. 2B may encompass one or more separate steps and/or operations. Accordingly, the recitation of only four steps in 210, 212, 214, and 216 should not be understood as limiting the method of the present invention solely to four steps or stages. Moreover, each representative step or stage 210, 212, 214, 216 should not be understood as being limited to a single process.

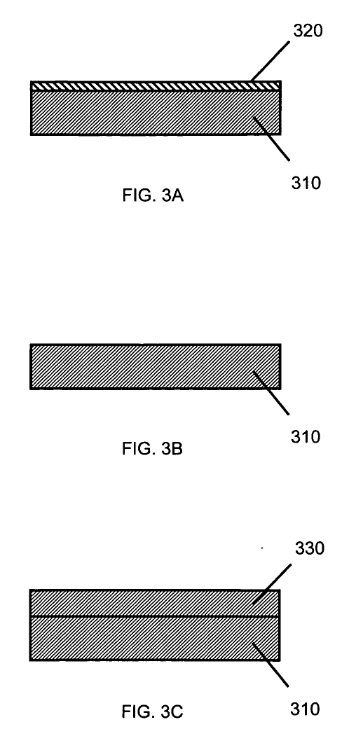

FIGS. 3A-3C schematically show oxide removal from a substrate and subsequent deposition of a film onto the cleaned substrate according to the process described in FIGS. 2A and 2B. FIG. 3A illustrates a substrate 310 having an oxide layer 320 thereon. According to an embodiment of the invention, the oxide layer 320 can be a native oxide layer of the 2-3 angstroms thick or up to about 10 angstroms thick. The substrate 310 can, for example, contain Si, SiGe, Ge, a glass substrate, a LCD substrate, or a compound semiconductor substrate. In one example, the presence of the oxide layer 320 on the substrate 310 can, if not removed, inhibit formation of a proper silicon-containing seed (nucleation) film and thereby affect deposition of a silicon-containing film on the substrate 310.

FIG. 3B illustrates the substrate 310 following removal of the oxide layer 320 according to an embodiment of the invention. As described above, the oxide layer 320 is removed by exposing the substrate 310 to an etching gas containing F₂. FIG. 3C illustrates the structure 300 following subsequent deposition of a film 330 onto the substrate 310. The film 330 can, for example, be an epitaxial Si film where the crystal lattice of the Si substrate 310 is extended through growth of the new Si film 330. Alternatively, the deposited film 330 can be a poly-Si film or an amorphous Si film. Or, the deposited film 330 can be SiGe film.

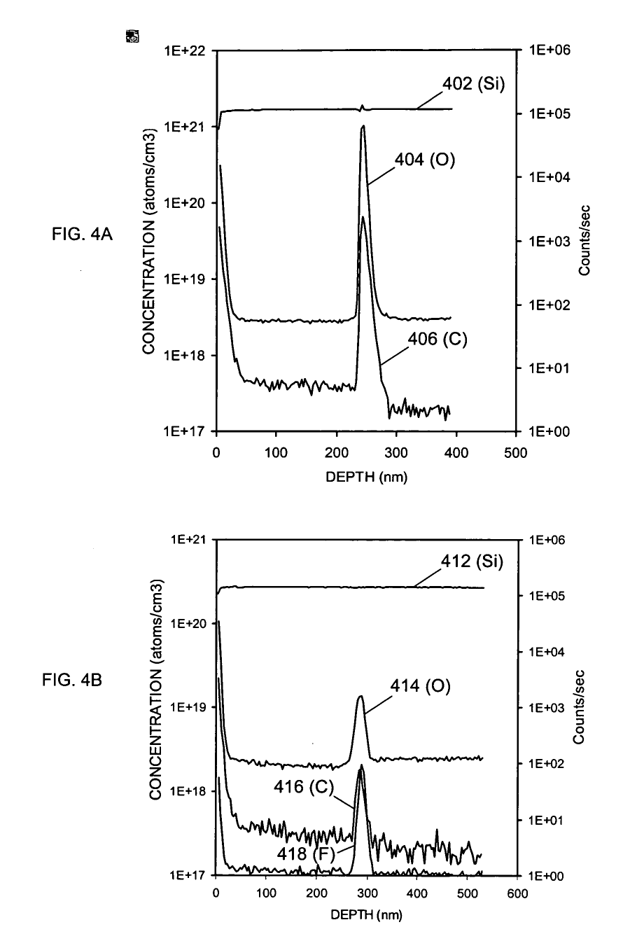

FIGS. 4A-4B illustrate SIMS depth profiles of poly-Si films deposited onto Si substrates with and without oxide removal according to an embodiment of the invention. The as-received Si substrates were first cleaned ex-situ (outside the process chamber) using standard HF wet cleaning and thereafter the Si substrates were transferred to the process chamber for further processing.

FIG. 4A illustrates SIMS depth profile of a poly-Si film deposited onto a HF-cleaned substrate, where silicon (Si), oxygen (O), and carbon (C) signals were monitored. The O signal corresponds to an O surface coverage of about 9.6×10¹⁴ atoms/cm² or an SiO₂ layer with a thickness of about 2.0 angstroms. It should be noted that the thickness of a single SiO₂ layer is about 4-5 angstroms and the oxide layer coverage is thus less than a single complete oxide layer. This demonstrates the sensitivity of SIMS depth profiling. The thickness of a native oxide layer on as-received (before HF cleaning) Si substrates is commonly between about 10-15 angstroms and the thin oxide layer (2 angstroms thick) shown in FIG. 4A was formed during transfer of the HF-cleaned Si substrate in air to the process chamber.

FIG. 4B shows a SIMS depth profile of a poly-Si film deposited onto a substrate that was HF cleaned ex-situ and further cleaned in the process chamber (in-situ) according to embodiments of the invention. The Si substrate was cleaned in-situ using an etching gas containing F₂ prior to deposition of the poly-Si film. The etching gas contained 8 slm N₂+1 slm of 20% F₂ in N₂, the substrate temperature was 300° C., the process chamber pressure was 1 Torr, and the oxide removal process was carried out for 30 min. Si, O, C, and F signals were monitored in FIG. 4B and the O signal corresponds to an O surface coverage of about 0.24×10¹⁴ atoms/cm² or an SiO₂ layer with a thickness of about 0.05 angstroms. It is contemplated that the O surface coverage (and thus the average SiO₂ thickness) can be further reduced by utilizing a higher purity etching gas.

Comparison of the depth profiles shown in FIGS. 4A and 4B demonstrates that the use of an etching gas containing F₂ according to embodiments of the invention result in very effective removal of an oxide layer at low substrate temperature.

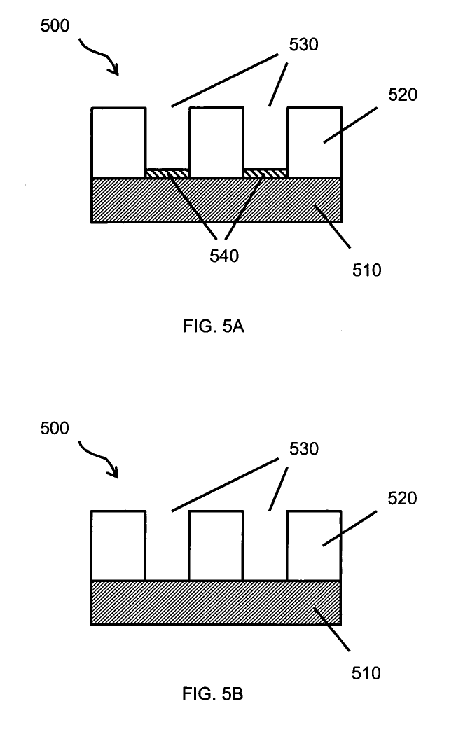

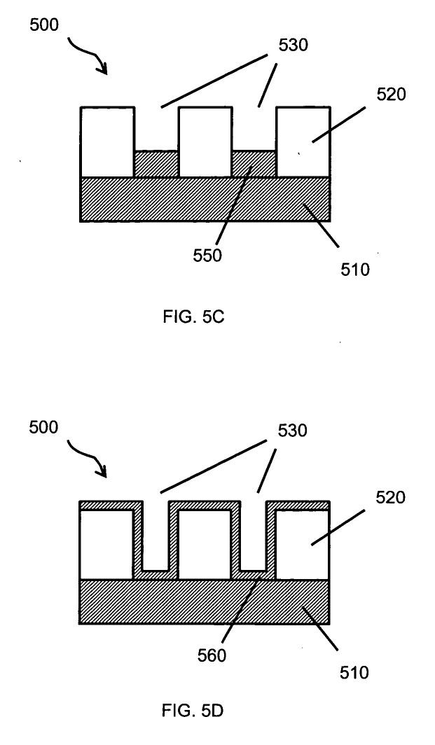

FIGS. 5A-5D schematically illustrate oxide removal from a patterned structure and subsequent deposition of a silicon-containing film onto the patterned structure according to an embodiment of the invention. FIG. 5A illustrates a patterned structure 500 containing a substrate 510, a patterned film 520, and oxide layers 540 formed on the substrate 510 in the openings 530. Although not shown in FIG. 5A, the patterned film 520 may also contain an oxide layer. The patterned film 520 can, for example, be a dielectric film such as a SiO₂ film, a SiON film, a low-k film, or a high-k film. The openings 530 can, for example, be vias or trenches, or combinations thereof. The patterned structure 500 is an exemplary structure used in the device manufacturing and can contain a silicon substrate 510 and an overlying photolithographically patterned film 520.

FIG. 5B illustrates the patterned structure 500 following removal of the oxide layers 540 from the openings 530 according to embodiments of the invention as described above.

FIG. 5C illustrates the patterned structure 500 following selective deposition of a film 550 onto the exposed portion of the substrate 510 according to embodiments of the invention. The selectively deposited film 550 can, for example, be an epitaxial silicon film deposited on a silicon substrate 510. The epitaxial silicon film 550 can, for example, be selectively deposited on the exposed portion of the silicon substrate 510, using, for example, a gas containing Si₂Cl₆ (HCD), a substrate temperature of between about 750° C. and about 850° C., for example at about 800° C. Further details of utilizing HCD gas to deposit silicon-containing films are described in U.S. patent application Ser. No. 10/673,375, titled “DEPOSITION OF SILICON-CONTAINING FILMS FROM HEXACHLORODISILANE.”

The selective deposition of the epitaxial silicon-containing film 550 allows for subsequent removal of the patterned film 520 from the Si substrate 510 using methods known to those skilled in the art, to form a raised epitaxial silicon-containing film 550 on the silicon substrate 510. In general, the patterned film 520 can include at least one of an oxide mask (e.g., SiO₂) and a nitride mask (e.g., Si₃N₄). The use of selective deposition of epitaxial silicon-containing films can be used for manufacturing silicon-on-insulator (SOI) devices with a raised source and drain regions. During SOI device fabrication, processing may consume an entire Si film in source and drain regions, thereby requiring extra Si in these regions that can be provided by selective epitaxial growth (SEG) of silicon-containing films. Selective epitaxial deposition of silicon-containing films can reduce the number of photolithography and etch steps that are needed, which can reduce the overall cost and complexity involved in manufacturing a device.

FIG. 5D illustrates the patterned structure 500 following non-selective (blanket) deposition of a film 560 onto the patterned structure 500 according to an embodiment of the invention. According to one embodiment of the invention, the film 560 can be a Si film. The Si film 560 can be deposited on the patterned structure 500 with substantially uniform thickness, regardless of the type of materials comprising the substrate 510 and the patterned film 520. In one example, a Si film 560 can be formed on the patterned structure 500 using a process gas containing Si₂Cl₆, a substrate temperature between about 550° C. and about 750° C. In another example, a process gas containing Si₂Cl₆ and SiH₄ may be used. As would be appreciated by those skilled in the art, the crystal structure of the deposited Si films can be a function of processing conditions, including substrate temperature, process pressure, and gas composition.

Although only certain embodiments of this invention have been described in detail above, those skilled in the art will readily appreciate that many modifications are possible in the exemplary embodiment without materially departing from the novel teachings and advantages of this invention. Accordingly, all such modifications are intended to be included within the scope of this invention.

What is claimed is:

1. A method for processing at least one substrate, comprising:
providing the at least one substrate in a process chamber, the at least one substrate having an oxide layer formed thereon; and
exposing the at least one substrate to a flow of an etching gas comprising F₂ at a temperature of not more than about 400° C. to substantially remove the oxide layer from the at least one substrate.

2. The method according to claim 1, further comprising:
heating the at least one substrate to a second temperature greater than the first temperature; and forming a film on the at least one substrate at the second temperature.

3. The method according to claim 1, wherein:
the etching gas further comprises an inert gas.

4. The method according to claim 3, wherein:
the inert gas comprises N₂, Ar, He, Ne, Kr, or Xe, or a combination of two or more thereof.

5. The method of claim 4, wherein said etching gas comprises approximately 20% F₂ and approximately 80% N₂.

6. The method of claim 4, wherein said etching gas comprises approximately 2%-20% F₂.

7. The method according to claim 3, wherein:
the etching gas comprises a reducing gas.

8. The method according to claim 7, wherein:
the reducing gas comprises H₂, H, or NH₃, or a combination of two or more thereof.

9. The method according to claim 1, wherein:
the exposing is performed at a process chamber pressure between about 0.1 Torr and about 100 Torr.

10. The method according to claim 1, wherein:
the exposing is performed at a process chamber pressure between about 1 Torr and about 10 Torr.

11. The method according to claim 2, wherein:
the forming comprises exposing the at least one substrate to a silicon-containing gas to deposit a Si-containing film.

12. The method according to claim 11, wherein:
the Si-containing film comprises poly-Si, amorphous Si, epitaxial Si, or SiGe.

13. The method according to claim 12, wherein:
the silicon-containing gas comprises SiH₄, SiCl₄, Si₂H₆, SiH₂Cl₂, or Si₂Cl₆, or a combination of two or more thereof.

14. The method according to claim 2, wherein:
the forming comprises exposing the at least one substrate to a silicon-containing gas containing (1) SiH₄, SiCl₄, Si₂H₆, SiH₂Cl₂, or Si₂Cl₆, or a combination of two or more thereof, and (2) a germanium-containing gas containing GeH₄ or GeCl₄, or a combination thereof.

15. The method according to claim 2, wherein:
the film comprises Si, SiGe, SiGeC, HfO₂, HfSiOₓ, HfSiOₓN_{y}, ZrO₂, ZrSiOₓ, or ZrSiOₓN_{y}.

16. The method according to claim 2, wherein:
the forming comprises exposing the at least one substrate to a plasma-excited silicon-containing gas.

17. The method according to claim 2, wherein:
the forming is performed at a process chamber pressure between about 0.1 Torr and about 100 Torr.

18. The method according to claim 17, wherein:
the at least one substrate comprises Si, SiGe, Ge, a glass substrate, a LCD substrate, or a compound semiconductor.

19. The method according to claim 1, wherein:
the first temperature is between about 20° C. and about 400° C.

20. The method according to claim 1, wherein:
the first temperature is between about 100° C. and about 300° C.

21. The method according to claim 1, wherein:
the first temperature is between about 200° C. and about 300° C.

22. The method according to claim 2, wherein:
the second temperature is between about 100° C. and about 900° C.

23. The method according to claim 19, wherein:
the second temperature is between about 100° C. and about 900° C.

24. The method according to claim 1, wherein:
the at least one substrate comprises at least one patterned substrate containing one or more vias or trenches, or combinations thereof.

25. The method according to claim 2, wherein:
the film is selectively formed on a silicon-containing surface of the at least one substrate.

26. The method according to claim 2, wherein:
the film is non-selectively formed on the at least one substrate.

27. A method for processing at least one Si substrate, comprising:
providing the at least one Si substrate in a process chamber, the at least one Si substrate having an oxide layer formed thereon; and
exposing the at least one Si substrate to a flow of an etching gas comprising F₂ at a first temperature less than about 400° C. to substantially remove the oxide layer from the at least one Si substrate.

28. The method according to claim 27, further comprising:
heating the at least one Si substrate to a second temperature between about 750° C. and about 850° C.

29. The method according to claim 28, further comprising:
forming an epitaxial Si film on the at least one Si substrate at the second temperature by exposing the at least one Si substrate to a gas comprising Si₂Cl₆.
